(19) United States
(12) Patent Application Publication
(10) Pub. No.: US 2014/0327441 A1
(43) Pub. Date: Nov. 6, 2014

(54) MEASURING FACILITY FOR MEASURING A MAGNETIC FIELD IN A MAGNETIC RESONANCE DEVICE, USE OF A MEASURING FACILITY AND MAGNETIC RESONANCE DEVICE

(71) Applicant: SIEMENS AKTIENGESELLSCHAFT, Munchen (DE)

(72) Inventor: LARS LAUER, NEUNKIRCHEN (DE)

(73) Assignee: SIEMENS AKTIENGESELLSCHAFT, Munchen (DE)

(21) Appl. No.: 14/261,596

(22) Filed: Apr. 25, 2014

(30) Foreign Application Priority Data
May 3, 2013 (DE) 102013208134.0

(51) Int. Cl. G01R 33/44

(52) U.S. Cl. CPC G01R 33/443
USPC 324/318

(57) ABSTRACT

A measuring facility for measuring a magnetic field in a magnetic resonance device, having:
a magnetic oscillating body attached so as to be able to move at least partly against a deflection-dependent resetting force of the magnetic field;
an excitation device for exciting the oscillating body into a free oscillation;
a sensor device for determining an oscillation frequency of the oscillating body oscillating freely in the magnetic field; and
an evaluation device for establishing the magnetic field strength from the oscillation frequency is provided.

### CROSS-REFERENCE TO RELATED APPLICATIONS

This application claims priority to DE Application No. 102013208134.0, having a filing date of May 3, 2013, the entire contents of which are hereby incorporated by reference.

### FIELD OF TECHNOLOGY

The following relates to a compact measuring facility for measuring a magnetic field in a magnetic resonance device, to a magnetic resonance device and to the use of a measuring facility.

### BACKGROUND

Magnetic resonance devices are already known in the prior art. In said devices an aspect to be imaged, for example a patient, is supported within a strong magnetic field. Spins are explicitly excited and signals are recorded during decay of the excitation. Of importance for the image quality and the measurement accuracy able to be obtained in magnetic resonance devices is the homogeneity of the basic field magnet B0 and also the linearity of the overlaid gradient fields, which are used for slice selection, for phase encoding and/or for readout. The homogeneity and/or linearity are subject to technical limits in real magnetic resonance devices. In such cases it should particularly be noted that even with a highly accurate layout or measurement beforehand, changes can result, for example caused by thermally-related effects or also by the aspect to be imaged itself, which distorts the magnetic field in the magnetic resonance device through its individual susceptibility.

In order to improve the homogeneity of the basic magnetic field and the linearity of the overlaid gradient fields, it is known for example to undertake what is referred to as a distortion correction of the gradient fields based on static correction tables established. A homogenization of the basic magnetic field is realized by so-called shim measures, by for example a one-off homogenization being carried out during installation of the magnetic resonance device, which is stabilized over time with an electrical interference shield.

However it would be desirable to detect the current magnetic field strengths during imaging using measurement technology, in order to be able to correct in the best possible way the temporal and spatial distortions arise. Therefore in the prior art so-called field cameras have been proposed, which are intended to allow a magnetic resonance measurement independent of the actual imaging and thus a determination of the magnetic field. In such cases for example small volumes of specific materials are surrounded by conductor loops for example in order to form a field camera. The measured magnetic fields are used to already enable field corrections to be carried out during the imaging, for example by using shim coils or the like, but also to make possible field variations in the construction of image datasets from the recorded raw data.

Such a process is described for example in an article by Bertram J. Wilm et al., “Higher Order Reconstruction for MRI in the Presence of Spatiotemporal Field Perturbations”, Magnetic Resonance in Medicine 65:1690-1701 (2011). In said article a field camera is used which consists of 16 water probes which are distributed evenly over a sphere with a diameter of 20 centimeters.

EP 1 582 886 A1 discloses a magnetic resonance method in which signals are recorded from patients and additional signals from at least one monitoring field probe which is disposed in the vicinity of the patient, surrounding the latter, wherein the signal recording is undertaken while the magnetic resonance sequence is being carried out. The additional data of the monitoring field probes is used to adapt the magnetic resonance so that inaccuracies in the field response of the gradient coils are corrected and the reconstruction of the magnetic resonance images or spectra is improved.

U.S. Pat. No. 8,093,899 likewise relates to the correction of field errors which are attributable to eddy currents, non-ideal gradients and heating effects, wherein, for correction of such errors by signal processing means, precise knowledge about their values has to be available. The patent relates to the improvement of field cameras using a small volume of active liquid of which the resonant frequency is proportional to the local magnetic field, wherein it is established however that field variations as a result of non-adapted magnetic susceptibilities of the liquid, of the measurement coil and of the housing degrade the measured values. Accordingly a jacket is proposed, containing a paramagnetic filler, which is adapted in its concentration so that the magnetic susceptibility of the jacket matches the magnetic susceptibility of the coil, so that the measurement can be improved.

### SUMMARY

The underlying aspect of the invention is therefore to create an alternate, technically more robust measurement option for highly-accurate determination of the magnetic field strength in a magnetic resonance device.

To achieve this aspect a measuring facility for measuring a magnetic field in a magnetic resonance device is provided in accordance with the embodiments, having:
A magnetic oscillating body at least partly movably attached against a deflection-dependent resetting force of the magnetic field,
An excitation device for exciting the oscillating body into free oscillation,
A sensor device for establishing an oscillation frequency of the oscillating body oscillating freely in the magnetic field, and
An evaluation device for establishing the magnetic field strength from the oscillation frequency.

The basic idea is thus to observe the mechanical oscillation movement (swinging movement) of an oscillating body in the magnetic field, wherein the oscillating body is able to be deflected from a basic position against a deflection-dependent resetting force which exists because of the magnetic field. Since the oscillating body is ferromagnetic, for example is formed from a movably-supported magnetic particle, the oscillation frequency depends on the strength of the local magnetic field, so that, as basically known from such oscillating systems, the magnetic field strength can be derived by an evaluation unit from the oscillation frequency, whereby the actual relationship, which is dependent on the actual embodiment of the measuring facility, can be determined for example by mathematical calculations and/or calibration measurements.

In order to obtain any free oscillation at all the oscillating body must ultimately be “initiated”, for which, whenever a measurement is to be made, an excitation device is activated in order to excite the oscillating body into free oscillation, so that thus a one-off mechanical impact is exerted on the oscillating body before the actual measurement is undertaken by the sensor device.

It should also be pointed out that these types of measuring facilities are built permanently into the magnetic resonance device since the field direction of the basic magnetic field which actually forms the main field components is known, so that the measurement device can be disposed such that the magnetic axis of the oscillating body corresponds to the field direction in its basic setting able to be influenced by the excitation device.

In this case the inventive measuring facility measures the oscillation frequency over a period of time in accordance with knowledge which underlies the embodiments that time measurements can be carried out highly-resolved, so that it is thus ultimately readily possible to even establish small frequency deviations which indicate field changes. The magnetic field strength measured by the measuring facility, wherein there are natural deviations from a basic magnetic field strength can be involved, as in the prior art known from the field cameras, can be used in a wide variety of ways, which is however known and is not the subject matter of the embodiments.

One of the advantages of the inventive measuring facility is that it can be realized as an extremely compact design, to which, as is explained in greater detail below, the type of components can contribute. Thus in general terms for example there can be provision for the oscillating body to have a maximum extent of less than 1 centimeter, or less than 5 millimeters, and/or a unit comprising at least the oscillating body in at least a part of the excitation device and the sensor device to have a maximum extent of less than 1 centimeter, especially less than 5 millimeters. Such a rather small embodiment of the measuring facility is also sensible to the extent that an oscillating body which is too large, especially too great a mass of the oscillating body, can lead to a perturbation of the field distribution per se. For oscillating bodies which have a maximum extent of 5 millimeters, less, the danger of an influencing of the measurement by the oscillating body itself is minimized. In addition this type of small measuring facility can also be integrated very well into the overall structure of a magnetic resonance device, in that measuring facilities can be disposed in the patient couch, the housing of local coils and the like.

Two different options are ultimately conceivable for embodying the oscillating body itself. Thus on the one hand there can be provision for the oscillating body to be embodied as an especially rotatably supported pendulum between a North pole and a South pole of the oscillating body. Such a pendulum, which is rotatably supported in the middle can also be referred to as a micro-pendulum, especially if it is realized as less than 5 millimeters, or less than 1 millimeter. The manufacturing of micro-mechanics for such small components is already known, so that it is readily possible to support a micro-pendulum as a ferromagnetic particle rotatable on a base body in order to realize the oscillating body.

Another variant of the embodiments makes provision for the oscillating body to be a small plate attached on one side to a base, oscillating freely on the other side. Such items can be realized in smaller sizes for example by layering methods by the oscillating body for example initially being applied as a layer and then some layers lying partially below said layer being removed, especially by etching, so that the freely oscillating part of the oscillating body is etched free. Naturally other variants are also conceivable for disposing a small plate of this type on a base oscillating freely to one side, for example by gluing and the like. This design of oscillating body can be referred to as a cantilever for example.

Different variants are also conceivable for realizing the excitation device, which especially aim to ensure a smallest possible field influencing, i.e. as great as possible magnetic resonance compatibility, which also applies to the embodiments of the sensor device presented below.

An exemplary embodiment makes provision for the excitation device to be a piezoelement, especially a piezo crystal. Piezoelements are already widely known, wherein mechanical forces are to be realized in miniaturize. In such cases a voltage is applied to the piezoelement having piezoelectric properties, which results in deformation, which in accordance with the embodiment is converted into an excitation force for the oscillating body or serves directly as set forth. This means that the oscillating body is impelled into free oscillation by the piezoelement. Since electrical energy is necessary for this purpose in order to create the voltage, the measuring facility can have an energy store and/or an energy generation facility, especially using changes in the magnetic field for supplying the piezoelement. For example a capacitor or the like can be used as the energy store, which is charged by energy created from magnetic field changes, but small miniaturized batteries and the like are also conceivable. In such cases it is preferred to hold and/or create the energy directly at the piezoelement, for example in a corresponding constructional unit, in order if necessary to avoid the effects restricting magnetic resonance compatibility as far as possible.

An alternate embodiment makes provision for the excitation device to be a pressure generator and to have a tube emerging into a space containing the oscillating body such that the oscillating body is excited into an excitation by a pressure wave generated by the pressure generator and conveyed through the tube. In this case the impetus for free oscillation is imparted by a pressure wave, thus especially by sound, so that there does not have to be any transmission of electrical signals and energy to the actual measurement unit in the magnetic field of the magnetic resonance device, but a tube transmitting the pressure wave merely has to be provided so that the pressure generator can be disposed outside the magnetic field. Such an embodiment is especially magnetic-resonance-compatible, since no or only extremely insignificant magnetic influences arise.

The sensor device is also created so that it offers the greatest possible magnetic resonance compatibility, thus no or just a few electrical or magnetic influences are needed, especially within the magnetic field.

In an exemplary embodiment, it is initially conceivable for the sensor device to comprise a microphone and a tube for transport of sound signals created by an oscillation of the oscillating body to the microphone and/or the evaluation device. In combination with a pressure generator and a corresponding tube as excitation device a measuring unit completely based on sound can thus be created, which also exhibits a high magnetic resonance compatibility. Since the oscillating body, through its oscillation, causes density changes in the surrounding air, these can be detected as sound waves by a highly-sensitive microphone, for example also forwarded via a membrane in a defined way into a tube, which then leads to the actual measurement data detection outside the magnetic field. As in the case of the excitation by a pressure wave it is also expedient here for the oscillating body to be located in an air-filled space, especially a closed space, which is realized using a corresponding unit.

Within the context of the embodiments, in an alternate exemplary embodiment, for the sensor device to comprise an optical sensor and a light source, wherein light created by the light source is able to be received as a function of the position of the oscillating body by the optical sensor. In this way an optical measuring principle can be realized which can also largely or entirely do without external electrical energy and/or signal transmission. Such optical measurement methods for determining an oscillation or also rotational frequency of an oscillating rotating body are known in the prior art for example from fluid counters and are based on monitoring a deflection position of the oscillating body, wherein different signals are created in the optical sensor depending on whether the oscillating body is located in the monitored deflection position or not. An oscillation frequency can be established easily from this.

In such cases different embodiments are conceivable, wherein there can be provision on the one hand for the light source and the sensor to the realized as a single device, thus the light to be measured is then for example, when the oscillating body is located in the observed deflection position, reflected from said body, is captured again and is measured. In this case it is especially expedient if the oscillating body is made of a reflective glass. However embodiments are naturally also conceivable in which the light source and the optical sensor represent separate constructional units, for example by the light being coupled into a constructional unit containing the oscillating body opposite the optical sensor and the light path being interrupted by the oscillating body oscillating into it, hence whenever the oscillating body is located in the observed deflection position, no light is received. Other arrangements of light source and optical sensor in relation to one another are of course conceivable.

To this end it can also be expedient for a reflector reflecting the light of the light source, moving with the oscillating body, to be provided on the oscillating body and/or for at least a part of the oscillating body itself to act as a reflector. Additional components can for example be reflective items disposed on the oscillating body, naturally-reflecting coatings and the like are also conceivable. As already noted, it is also conceivable to embody the oscillating body itself so that it is delivered from the factory with reflective portions, for example when the oscillating body is produced from glass using conventional production techniques.

The optical sensor can be embodied as a photodiode and/or the light source as a laser diode. Both components can be realized miniaturized, especially on a semiconductor chip, a topic which will be discussed in greater detail below. Of course other embodiments are also basically conceivable however.

Using an optical measuring principle has the further advantage of enabling optical waveguides to be employed. Thus it is conceivable for the measuring facility to comprise at least one optical waveguide for transport of light to the light source and/or to the sensor or from the sensor to the evaluation device. Thus for example there can be provision for the light source to ultimately be formed by an outlet or an outlet optic of an optical waveguide, wherein the light is created outside the magnetic resonance device and thus outside the magnetic field to be measured. Similarly it is possible to realize the data transmission from the sensor to the evaluation device optically; however the optical signal to be measured, i.e. the light itself, is transmitted through an optical waveguide to the sensor disposed remotely, especially outside the magnetic resonance device or outside its patient support. In this way influence on the magnetic field to be measured is further reduced.

As has already been explained, it is conceivable for the oscillating body to consist of glass. Favorable production methods for magnetic glass bodies having suitable properties for the inventive measuring device are already known in the prior art. Such an oscillating body, as has already been explained, is especially advantageous in conjunction with optical measuring methods.

In an especially advantageous embodiment the oscillating body and at least one part of the excitation device and/or of the sensor device can be realized on a semiconductor chip. The measurement unit can be disposed in this way highly-integrated and cost-effectively onto the semiconductor chip in micro-technical production processes, wherein such a measurement unit can also be referred to as a measurement module. In this case it is expedient to arrange at least a part of the components by layering methods on the semiconductor chip; however hybrid production, in which parts are glued on or the like, are conceivable.

Overall, with the inventive measuring facility a highly-accurate, highly-integrated and low-cost probe can thus be provided for monitoring the magnetic field strength in a magnetic resonance device.

As well as the measuring facility the embodiment also relates to a magnetic resonance device, including at least one inventive measuring facility. The embodiments of the measuring facility can be transferred analogously to the magnetic resonance device, so that the corresponding advantages are likewise obtained.

As has already been discussed, there can be provision for a constructional unit of the measurement device including the oscillating body to be permanently installed such that the magnetic oscillating body, in its basic position able to be influenced by the excitation device, is orientated at least during the measurement along the field lines of the basic field. This means the magnetic axis of the oscillating body at rest coincides with the previously known field lines of the basic field and is selected so that the mechanical impetus can be imparted by the excitation device. The measuring facilities, since normally a number of facilities are provided, are built into the patient couch in such cases, wherein it is also conceivable to provide local coils to be installed in specific fixed orientations with measuring facilities of the inventive type.

In such cases the fixed, defined arrangement relating to the field lines of the basic magnetic field naturally refers for a patient couch to a receiving position of the patient couch.

Finally the embodiments also relate to the use of an inventive measuring facility for measuring a magnetic field in a magnetic resonance device, thus to the concrete application of the measuring facility. Here too everything that has been said in relation to the measuring facility can be transferred analogously. The measuring facility, as has been illustrated, especially has advantages in relation to magnetic resonance compatibility; in addition it can be realized as a compact, low-cost and highly-integrated device, so that an alternative to the field cameras known from the prior art is provided.

### BRIEF DESCRIPTION

Some of the embodiments will be described in detail, with reference to the following figures, wherein like designations denote like members, wherein:

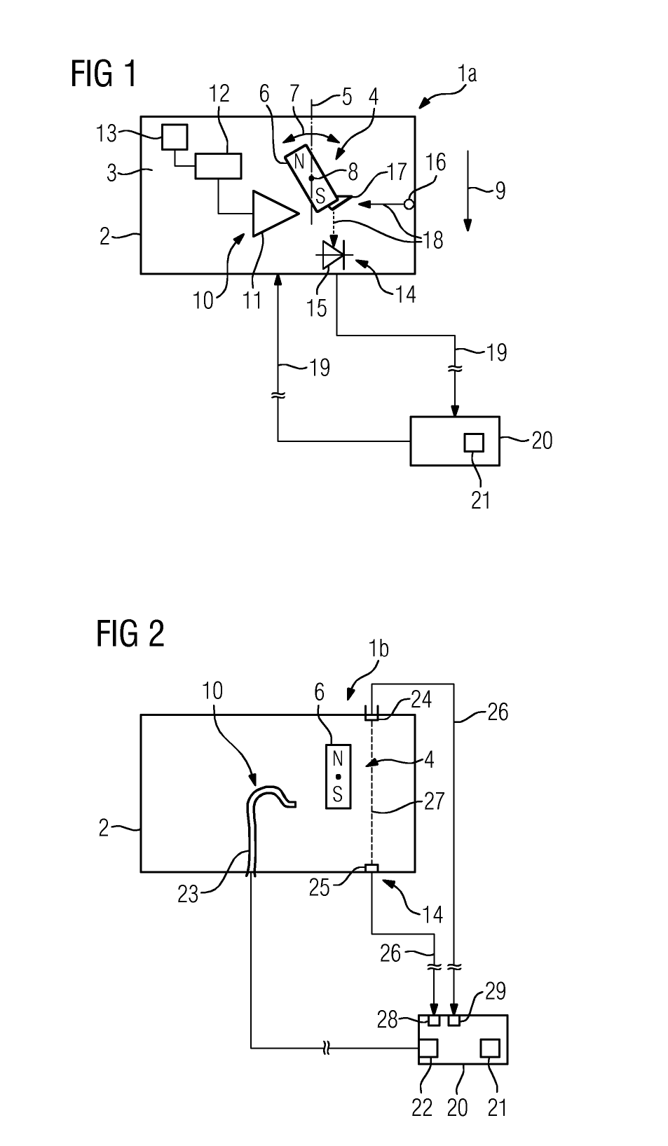

FIG. 1 depicts a first exemplary embodiment of an inventive measuring facility;

FIG. 2 depicts a second exemplary embodiment of an inventive measuring facility;

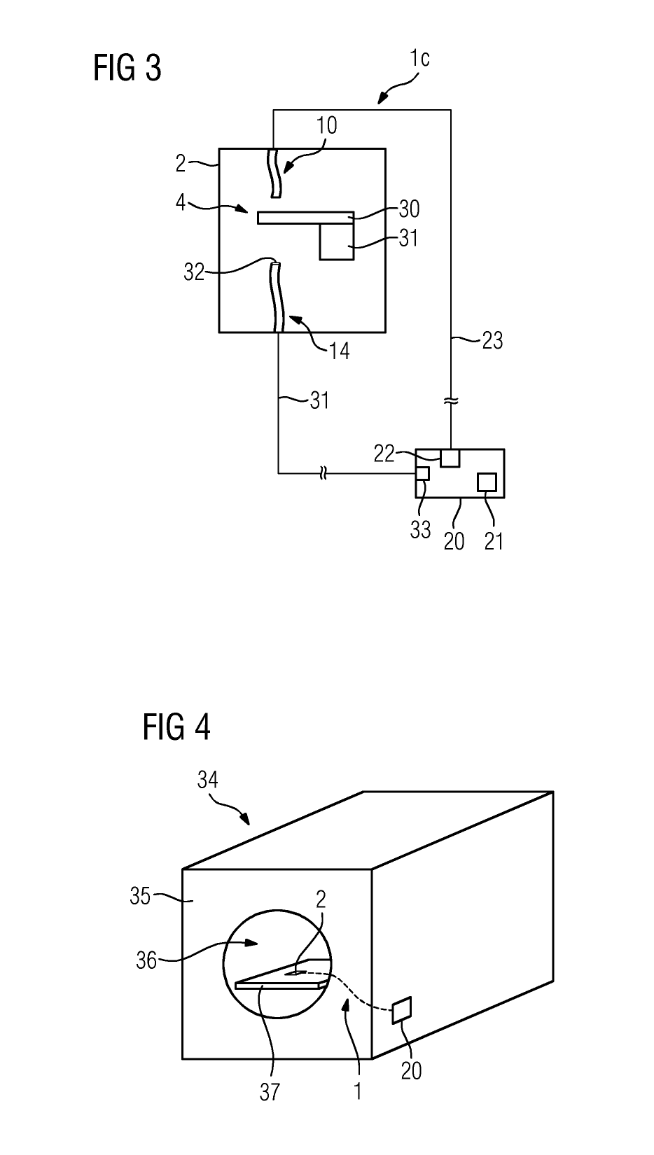

FIG. 3 depicts a third exemplary embodiment of an inventive measuring facility;

FIG. 4 depicts an inventive magnetic resonance device;

FIG. 5 depicts a patient couch of the inventive magnetic resonance device; and

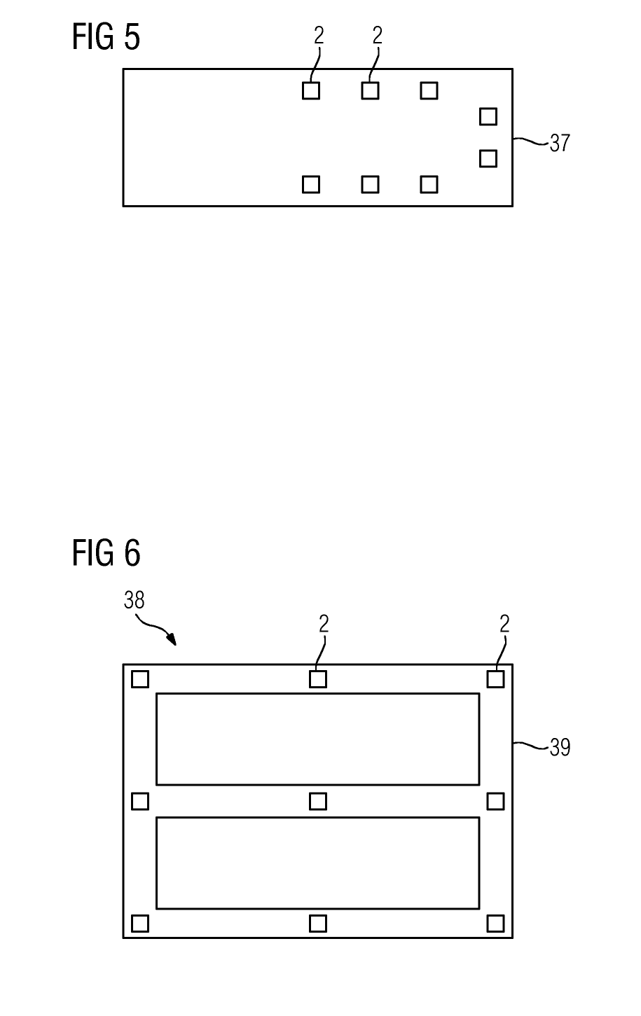

FIG. 6 depicts a local coil.

### DETAILED DESCRIPTION

A number of exemplary embodiments of an inventive measuring facility will now be presented below. These are basically constructed so that an at least partly movable magnetic oscillating body is used to which an excitation device imparts a free oscillation, of which the oscillation frequency is then measured via a sensor device and evaluated via an evaluation device. The measurement facilities are used for measuring the magnetic field within a patient chamber of a magnetic resonance device, wherein only a constructional unit comprising the oscillating body is located within the patient chamber. The evaluation device and if necessary parts of the sensor device and/or of the excitation device are arranged outside the patient chamber, which will be explained in greater detail below. The constructional unit comprising the oscillating body in this case is basically realized as a compact unit, meaning that for all exemplary embodiments, the maximum dimension of the constructional unit, for example an external length of the housing, is less than 5 millimeters. The oscillating body in this case is thus embodied even smaller, for example less than 3 millimeters or even less than 1 millimeter.

It should also be noted in this context that features of the exemplary embodiments shown here are naturally, where sensible, able to be interchanged between the different exemplary embodiments, especially as regards the embodiments of the oscillating body, the sensor device and the excitation device. For the sake of simplicity the same components are labeled with the same reference characters.

FIG. 1 shows a first exemplary embodiment of an inventive measuring facility 1a for measuring a magnetic field in a patient chamber of a magnetic resonance device. A first constructional unit 2, which is to be disposed where the magnetic field is to be measured, has a semiconductor chip 3 within a housing on which various principally shown components of the measuring facility 1a are disposed. On the one hand a magnetic oscillating body 4 is provided in the constructional unit 2, which is realized in the present invention as a rotatable deflectable pendulum 6 made of a magnetic particle. In the magnetic field of the magnetic device to be measured the pendulum 6 is directed in a basic position (idle position indicated by the dashed line 5) from which it is able to be deflected against a resetting force dependent on the magnetic field strength.

It can be seen that on excitation, i.e. imparting an impetus to the oscillating body 4, an oscillating movement indicated by the arrow 7 is produced, wherein in this example the oscillating body 4 is shown in a deflected position, meaning that its magnetic axis is rotated out of the basic position marked by the line 5. The poles of the pendulum 6 are indicated by N for North and S for South, wherein the rotatable support can be seen as having been realized in the center, cf. rotational support unit 8. With increasing deflection from the basic position in which the magnetic axis of the oscillating body 4 corresponds to the direction of the magnetic field, as is well known, the resetting force of the magnetic field increases.

The constructional unit 2 of the measuring facility 1a is disposed within the patient chamber, so that the location of the magnetic axis, in the idle position of the field direction shown by the line 5, corresponds to the field direction of the basic magnetic field of the magnetic resonance device, indicated by the arrow 9. Thus a micromechanical device is realized overall in which the oscillating body 4 can be deflected from an idle position against a resetting force and then oscillates freely at an oscillation frequency depending on the magnetic field strength.

In order to create the initial deflection required for the measurement, an excitation device 10 is provided which can exert a mechanical impetus to the oscillating body 4. This is realized in the present exemplary embodiment by a piezoelement 11, here a piezocrystal. This obtains its electrical energy from an energy store 12 which is connected to an energy generation device 13, which uses changes in the magnetic field to generate energy in a small, adequate amount and stores it in the energy store 12, which can for example be embodied as a capacitor.

So that the oscillation frequency can be detected a sensor device 14 is also provided. In the present case this comprises a photodiode 15 which, in a specific deflection state of the oscillating body 4, receives light of a laser diode 16, which occurs in the present example via a reflector 17 moving with the oscillating body and attached to said body. As the arrows 18 show, a position of the oscillating body 4 is shown in which light of the laser diode 16 is received by the photodiode 15. If the oscillating body 4 oscillates back in the direction of the basic position, the alignment of the reflector 17 changes and the photo diode no longer measures any light. In alternate exemplary embodiments the oscillating body 4 itself can also be embodied reflectively, consisting of glass for example.

For activating and for reading out the constructional unit 2 said unit is connected to a second constructional unit 20, which is disposed outside the patient chamber of the magnetic resonance device, via control lines 19 only indicated here, in order to minimize the influencing of the magnetic field by the measuring facility 1a. The constructional unit 20 contains an evaluation device 21 which also functions as a control device, thus being able to put measurements into effect and the like by activating the piezoelement 11. In each case the evaluation device 21 is embodied to convert the measured oscillation frequency into a magnetic field strength. It should also be noted that the control lines 19 for the measuring facility 1a can also be realized optically, for example by corresponding optocouplers being used.

FIG. 2 shows a second exemplary embodiment of an inventive measuring facility 1b. In this facility a pendulum 6 is again provided as the oscillating body in the constructional unit. What has been stated as regards the measuring facility 1a can thus be transferred analogously. What is changed by comparison with FIG. 1 is the embodiment of the excitation device 10 and the sensor device 14. The excitation device 10 here comprises a pressure generator 22, which is disposed in the constructional unit 20 and can generate a pressure wave, which is conveyed through a tube 23 to the oscillating body 4, so that said body can be deflected from the idle position, meaning that the free oscillation process begins. The oscillation frequency is again measured optically, only here an optical waveguide 26 is provided in each case opposite the optics 24, 25. Via one of the optical waveguide's 26 light is conveyed to optic 24, which thus serves as a light source. If the pendulum, as shown, is in the idle state the light passes through the light path 27 and is captured by the optic 25, wherein it is conveyed by means of the other optical waveguide 26 to a photodiode 28 as the sensor, which in the present example is provided in the second constructional unit 20 located outside the patient chamber, which also contains the corresponding light generator 29.

If the pendulum 6 is now deflected by the oscillation process, it moves into the light path 27, so that the optic 25 does not receive light any longer because of shadowing, meaning that the oscillation movement and the oscillation frequency can be measured.

A semiconductor chip is no longer necessary in the constructional unit 2 since all components can be realized micromechanically. In addition no electrical energy stores, energy sources and lines are needed any longer within the constructional unit 2 or to the constructional unit 2, so that a high magnetic resonance compatibility is provided.

FIG. 3 shows a third exemplary embodiment of an inventive measuring facility 1c. In this embodiment the constructional unit 2 is embodied as a small chamber defined by a housing in which the oscillating element 4 embodied here as a small plate 30 oscillating freely on one side is attached to a base 31. Two tubes 23 and 31 lead to the oscillating body 4, starting from the second constructional unit 20, wherein the tube 23 is once again connected to a pressure generator 22 which sends out a pressure wave for excitation of the oscillating body 4, thus forming part of the excitation device 10, which is embodied as shown in FIG. 2. Since their density fluctuations also occur through the free oscillation of the small plate 30, these are transferred in a defined manner via a membrane 32 into the tube 31, which ends at a highly-sensitive microphone 33, which can thus measure the oscillation frequency of the small plate 30 and passes this measurement on to the evaluation device 21.

The small plate 30 as the oscillating body can be realized in this case by a layering technique by the free space being created below the free oscillation area of the small plate 30 by an etching process, which serves as a space for the oscillation.

Here too no electrical energy or electrical signals are thus necessary in the area of the constructional unit 2.

FIG. 4 shows a basic sketch of an inventive magnetic resonance device 34. This has a main magnet unit 35 which defines a patient chamber 36 into which a patient couch 37 can be moved. The basic structure of such a magnetic resonance device is already known and will not be presented in any greater detail here.

The magnetic resonance device 34 has at least one inventive measuring device 1, i.e. at least one measuring device 1a, 1b or 1c for example. In this case, as described, the first constructional unit 2 is disposed within the patient chamber 36 when a measurement is to be undertaken. The constructional unit 2 is disposed here fixed to the patient couch 37, wherein the arrangement, as has been explained, is selected so that the magnetic axis of the oscillating body 4 matches the direction of the basic magnetic field of the magnetic resonance device 34 in a basic position in which the excitation device 14 can initiate the oscillating body 4, when the couch is moved into the patient chamber 36. Naturally other arrangements of the constructional unit 2 are also conceivable, for example in a guide for the patient couch 37 or on other completely immobile parts of the magnetic resonance device 34.

FIG. 5 shows a basic sketch of the patient couch 37. It can be seen that a plurality of first constructional units 2 is integrated into said couch at different locations. This enables the magnetic field strength to be measured at different points around the patient.

In order to supplement this, it is possible, cf. FIG. 6, to also integrate the measuring facility 1 via the constructional unit 2 into local coils 38, wherein FIG. 6 basically shows the rigid housing 39 of the local coil 38 to be placed on the patient couch 37 in a defined manner. Here too, at various locations at which field measurements are to be undertaken, constructional units 2 of the inventive measuring facilities 1 are disposed.

It should be pointed out that with an optical measuring method, cf. also FIG. 1 or FIG. 2 in this regard, it is also possible to realize the light source and the sensor as a single device.

Although the invention has been illustrated and described in greater detail by the exemplary embodiment, the invention is not restricted by the disclosed examples and other variations can be derived herefrom by the person skilled in the art, without departing from the scope of protection of the invention.

1. A measuring facility for measuring a magnetic field in a magnetic resonance device, having:
a magnetic oscillating body attached so as to be able to move at least partly against a deflection-dependent resetting force of the magnetic field,
an excitation device for exciting the oscillating body into a free oscillation,
a sensor device for establishing an oscillation frequency of the oscillating body oscillating freely in the magnetic field, and
an evaluation device for establishing the magnetic field strength from the oscillation frequency.

2. The measuring facility as claimed in claim 1, wherein the oscillating body has a maximum extent of less than 1 cm, and/or a constructional unit comprising at least the oscillating body and at least a part of the excitation device and the sensor device has a maximum extent of less than 1 cm.

3. The measuring facility as claimed in claim 1, wherein the oscillating body is embodied as a pendulum, especially supported rotatably between a North pole and a South pole of the oscillating body and/or as a small plate attached on one side to a base, oscillating freely on the other side.

4. The measuring facility as claimed in claim 1, wherein the excitation device is a piezoelement, especially a piezocrystal.

5. The measuring facility as claimed in claim 4, wherein it has an energy store and/or an energy generation facility, especially using changes in the magnetic field for supplying the piezoelement.

6. The measuring facility as claimed in claim 1, wherein the excitation device comprises a pressure generator and a tube opening out into a space containing the oscillating body such that the oscillating body is able to be excited into an oscillation by a pressure wave generated by the pressure generator and conveyed through the tube.

7. The measuring facility as claimed in claim 1, wherein the sensor device comprises a microphone and a tube for transport of sound signals generated by an oscillation of the oscillating body to the microphone and/or the evaluation device.

8. The measuring facility as claimed in claim 1, wherein the sensor device comprises an optical sensor and the light source, wherein light generated by the light source is able to be received by the optical sensor as a function of the position of the oscillating body.

9. The measuring facility as claimed in claim 8, wherein a reflector moving with the oscillating body, reflecting the light of the light source, is provided on the oscillating body.

10. The measuring facility as claimed in claim 8, wherein the sensor is embodied as a photodiode and/or the light source is embodied as a laser diode.

11. The measuring facility as claimed in claim 8, wherein the light source and the sensor are realized as a single device.

12. The measuring facility as claimed in claim 8, wherein it comprises at least one optical waveguide for transporting light to the light source and/or to the sensor or from the sensor to the evaluation device.

13. The measuring facility as claimed in claim 1, wherein the oscillating body consists of glass.

14. The measuring facility as claimed in claim 1, wherein the oscillating body and at least a part of the excitation device and/or of the sensor device are realized on a semiconductor chip.

15. A magnetic resonance device, comprising at least one measurement facility as claimed in claim 1.

16. The magnetic resonance device as claimed in claim 15, wherein a constructional unit of the measuring facility comprising the oscillating body is constructed such that the magnetic oscillating body in its basic setting able to be influenced by the excitation device, at least during the measurement is oriented along the field lines of the basic field.

17. Use of a measuring facility as claimed in claim 1 for measuring a magnetic field in a magnetic resonance device.

18. The measuring facility as claimed in claim 1, wherein the oscillating body has a maximum extent of less than 5 mm, and/or a constructional unit comprising at least the oscillating body and at least a part of the excitation device and the sensor device has a maximum extent of less than 5 mm.
